(19) United States
(12) Patent Application Publication
(10) Pub. No.: US 2020/0300923 A1
(43) Pub. Date: Sep. 24, 2020

(54) AUTOMATIC TEST SYSTEM OF WIRELESS CHARGING SYSTEM

(71) Applicant: Sichuan Energy Internet Research Institute, Tsinghua University, Chengdu (CN)

(72) Inventors: Tun LI, Chengdu (CN); Siming PAN, Chengdu (CN); Dawei HE, Chengdu (CN); Yi LIU, Chengdu (CN); Jingdong SUN, Chengdu (CN)

(21) Appl. No.: 16/896,570

(22) Filed: Jun. 9, 2020

Related U.S. Application Data
(63) Continuation of application No. PCT/CN2018/083639, filed on Apr. 19, 2018.

(30) Foreign Application Priority Data
Dec. 13, 2017 (CN) 201711324093.3

(51) Int. Cl. G01R 31/42; G01R 1/04; H02J 7/02; H02J 50/10

(52) U.S. Cl. CPC G01R 31/42; H02J 50/10; H02J 7/02; G01R 1/04

(57) ABSTRACT

An automated testing system for testing a wireless charging system is disclosed. The automated testing system may include a mechanical arm, a testing plane, a dock station and a controller computer. The mechanical arm is configured to hold a first device-under-test (DUT) clamp. The testing plane is configured to hold a second DUT clamp. The dock station is connected to the mechanical arm. The controller computer is configured to control the mechanical arm and receive testing data. The second DUT clamp is configured to hold a device-under-test of the wireless charging system, and the first DUT clamp is configured to hold a testing device for testing the device-under-test and generating the testing data.

### CROSS REFERENCE TO RELATED APPLICATIONS

This present application is a continuation of International Patent Application No. PCT/CN2018/083639, filed on Apr. 19, 2018, titled “Automatic Test System of Wireless Charging System”, which claims the benefit of and priority to Chinese Patent Application No. 201711324093.3, filed on Dec. 13, 2017. The above-referenced applications are herein incorporated by reference in their entirety.

### TECHNICAL FIELD

The disclosure relates generally to a wireless charging system, particularly, to an automated testing system for testing and characterizing a wireless charging system.

### BACKGROUND

Wireless charging is an evolving technology that may bring a new level of convenience of charging electronic devices. In a wireless charging system, particularly an inductive wireless charging system, energy is transferred from one or more power transmitter (TX) coils to one or more power receiver (RX) coils through coupling of magnetic fields.

A magnetic coil can generate magnetic fields, and the coupling of the magnetic fields between TX and RX coils may influence a charging efficiency of a wireless charging system. To improve user experiences and guarantee a reliability of the wireless charging, a wireless charging system should be thoroughly tested and characterized. Commonly used testing systems for characterizing a wireless charging system usually involve lots of human interactions, such as manually adjusting testing setups. Human interactions may introduce experimental errors and affect reliability of testing results. In addition, testing of a wireless charging system may include different testing conditions and scenarios for a wireless charging system at different stages, and the currently available testing systems cannot meet all different testing requirements and support all different testing scenarios.

The present application proposes an automated testing system for testing a wireless charging system. This automated testing system is able to evaluate a plurality of parameters for a wireless charging system at all development stages. In addition, it can be controlled both manually and automatically by a software program, thus the reliability and consistency of the testing results can be guaranteed.

### SUMMARY

One aspect of the present disclosure is directed to an automated testing system for testing a wireless charging system. The automated testing system may include a mechanical arm, a testing plane, a dock station and a controller computer. The mechanical arm is configured to hold a first device-under-test (DUT) clamp. The testing plane is configured to hold a second DUT clamp. The dock station is connected to the mechanical arm. The controller computer is configured to control the mechanical arm and receive testing data. The second DUT clamp is configured to hold a device-under-test of the wireless charging system, and the first DUT clamp is configured to hold a testing device for testing the device-under-test and generating the testing data.

Another aspect of the present disclosure is directed to an automated testing system for testing a wireless charging system. The system may include a mechanical arm, a testing plane configured to hold a device-under-test of the wireless charging system, a dock station connected to the mechanical arm, and a controller computer configured to control the mechanical arm and receive testing data. The mechanical arm may comprise a distal section configured to be releasably coupled to a plurality of types of devices selected from a clamp, a probe, and a testing device. The controller computer may comprise a non-transitory computer-readable medium that stores program code to control testing processes, measure and analyze the testing data.

Another aspect of the present disclosure is directed to an automated testing system for testing a wireless charging system. The system may include a mechanical arm configured to hold a first DUT clamp, a testing plane configured to hold a second DUT clamp, a dock station connected to the mechanical arm, and a controller computer configured to control the mechanical arm and receive testing data. The first and second DUT clamps may include a connector configured to be electrically coupled with devices for testing. The mechanical arm may comprise an internal data line through which the device coupled by the first DUT clamp communicates with the controller computer.

It is to be understood that the foregoing general description and the following detailed description are exemplary and explanatory only, and are not restrictive of the invention, as claimed.

### BRIEF DESCRIPTION OF THE DRAWINGS

The accompanying drawings, which constitute a part of this disclosure, illustrate several non-limiting embodiments and, together with the description, serve to explain the disclosed principles.

FIG. 1 is a graphical representation illustrating an automated testing system, consistent with exemplary embodiments of the present disclosure.

FIG. 2 is a graphical representation illustrating an automated testing system installed with a device-under-test (DUT) clamp, consistent with exemplary embodiments of the present disclosure.

FIG. 3 is a graphical representation illustrating an automated testing system for measuring magnetic fields generated by a magnetic coil, consistent with exemplary embodiments of the present disclosure.

FIG. 4 is a graphical representation illustrating an automated testing system for measuring an efficiency and charging area of a wireless charging system, consistent with exemplary embodiments of the present disclosure.

FIG. 5 is a graphical representation illustrating an automated testing system for measuring a coupling coefficient of a wireless charging system, consistent with exemplary embodiments of the present disclosure.

### DETAILED DESCRIPTION OF THE EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments consistent with the present invention do not represent all implementations consistent with the invention. Instead, they are merely examples of systems and methods consistent with aspects related to the invention.

A development of a wireless charging system may go through a plurality of stages, and at each stage, testing and characterization of the wireless charging system may request different conditions and scenarios. For example, in an early coil-design stage, the wireless charging system may need to be evaluated for uniformity of magnetic fields generated by magnetic coils. In a prototype validation stage, an estimation of efficiency and critical voltages (such as a rectifier voltage) of the wireless charging system may be required. In a post product stage, a charging area and a temperature of the wireless charging system may need to be characterized. Further, in a product certification stage, a radiation of the wireless charging system may need to be tested and limited. In this disclosure, we present an automated testing system for testing and characterizing a wireless charging system. The automated testing system can be used to test a wireless charging system in various stages, and meet various testing conditions and scenarios.

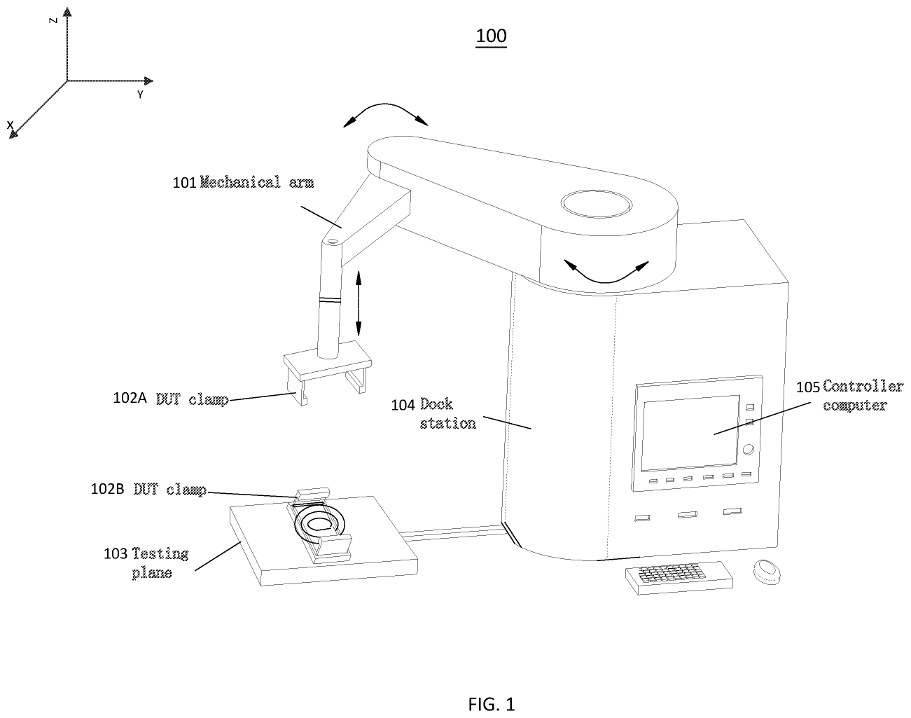

FIG. 1 shows an automated testing system 100, consistent with exemplary embodiments of the present disclosure. The system 100 may comprise a number of components, some of which may be optional. In some embodiments, the system 100 may include many more components than those shown in FIG. 1. However, it is not necessary that all of these components be shown in order to disclose an illustrative embodiment.

As shown in FIG. 1, the system 100 may include a mechanical arm 101, a device-under-test (DUT) clamp 102A mounted on the mechanical arm 101, a testing plane 103, a stationary DUT clamp 102B mounted on the testing plane 103, a dock station 104, and a controller computer 105.

In some embodiments, a DUT clamp can have any form suitable for holding a testing device or a device-under-test. For example, the DUT clamp can be a brace, a screw, a socket, etc. The testing device and device-under-test can be, for example, a magnetic coil, a printed circuit board (PCB), a magnetic probe, a mobile phone, or any wireless charging related electronic product.

The mechanical arm 101 may include a distal section configured to be releasably coupled to a plurality of types of devices selected from a clamp, a probe, a magnetic coil testing device, etc. In some embodiments, the mechanical arm 101 is configured to hold the DUT clamp 102A. In order to move and rotate in x, y and z directions, the mechanical arm 101 may include sliding and rotating motors. The mechanical arm 101 may be configured to hold and rotate the DUT clamp 102A in a [−180, 180] degree range about a center axis of the DUT clamp 102A, and move the DUT clamp 102A along the x, y and z directions to reach different positions.

The testing plane 103 may be a flat plane that is horizontally positioned with the surface of the plane parallel to the ground, and is also parallel to the x-y plane. The DUT clamp 102B (i.e., stationary DUT clamp) may be installed on the testing plane 103, and may be used to secure a device-under-test during testing.

Positions of the testing device and the device-under-test may be interchangeable. In one embodiment, the testing device may be secured on a movable DUT clamp 102A on the mechanical arm 101, and the device-under-test may be secured on a stationary DUT clamp 102B on the testing plane 103. In another embodiment, the testing device may be secured on a stationary DUT clamp 102B on the testing plane 103, and the device-under-test may be secured on a movable DUT clamp 102A on the mechanical arm 101.

The dock station 104 may include the controller computer 105. The mechanical arm 101 may be rotatably mounted on the dock station 104. The testing plane 103 may also be connected to the dock station 104. The controller computer 105 may drive the motors on the mechanical arm 101 to move the movable DUT clamp 102A to a target position. The controller computer 105 may provide a user-friendly interface and provide several pre-defined testing processes for user to choose. The controller computer 105 may be coupled with the mechanical arm 101 and the testing plate 103, and may control the mechanical arm 101 by driving the sliding and rotating motors. The controller computer 105 may also provide a user-friendly interface and software programs to control the testing process and analyze the testing results. In addition, the controller computer 105 may read testing data from instrument or DUT clamps to complete a post-processing procedure automatically.

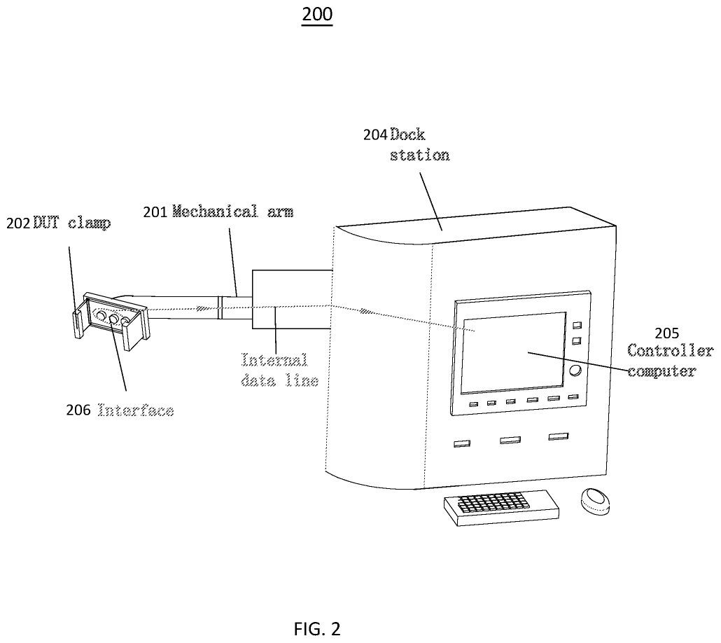

FIG. 2 is a graphical representation illustrating a DUT clamp 202 installed on an automated testing system 200 according to exemplary embodiments of the present disclosure. In addition to holding a testing device and a device-under-test, the DUT clamp 202 may be also configured to communicate with the controller computer 205 through internal data lines built in the mechanical arm 201, and accordingly the DUT clamp 202 may be designed with different interfaces 206.

In some embodiments, the interface 206 may include one or more electrical connectors including a plurality of hook-up wires for measuring voltages. The hook-up wires can couple with testing pins of a testing device, for example, a RX PCB. Through the coupling of the hook-up wires and the testing pins, output voltages from the testing device can be measured. The measured data then can be sent to the controller computer 205, so that the controller computer 205 can monitor and record voltage values detected by the testing device during testing.

In some embodiments, the interface 206 may include a data connector, and the data connector can couple with the testing device for data exchange between the testing device and the controller computer 205. The controller computer 205 may send controlling commends and receive feedbacks during the testing. The interface 206 allows the testing device to be electrically coupled and communicate with the controller computer 205. Thus, the automated testing system 200 can perform an in-situ testing on the wireless charging system.

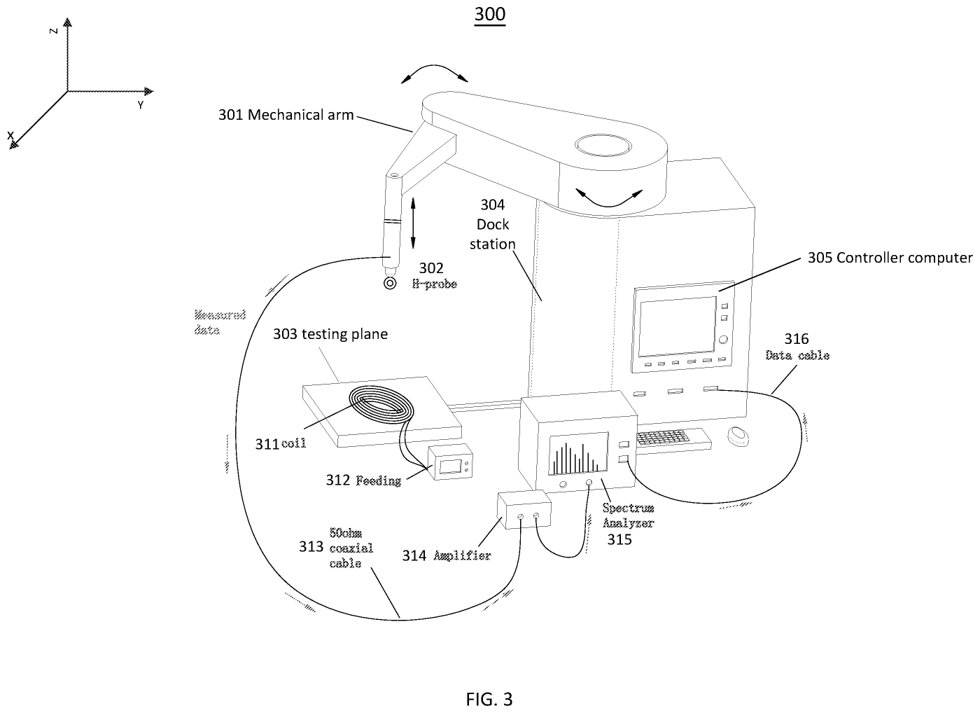

FIG. 3 shows an automated testing system 300 for measuring magnetic field (H-field) generated by a magnetic coil, consistent with exemplary embodiments of the present disclosure. The system 300 may comprise a number of components, some of which may be optional. In some embodiments, the system 300 may include many more components than those shown in FIG. 3. However, it is not necessary that all of these components be shown in order to disclose an illustrative embodiment.

As shown in FIG. 3, the system 300 may include a mechanical arm 301, an H-field probe 302, a testing plane 303, a dock station 304, a controller computer 305, as well as a magnetic coil 311, a feeding power supply 312, a cable 313, an amplifier 314, a testing instrument 315 and a data cable 316.

In some embodiments, a stationary DUT clamp may be placed on the testing plane 303 to hold a DUT, for example, the magnetic coil 311, a PCB prototype or a wireless charging related product. A device-under-test is interchangeable based on different testing requirements and scenarios. In some embodiments, the DUT is a magnetic coil. In some embodiments, the DUT is a TX coil.

In some embodiments, a movable DUT clamp may be used to hold the H-field probe 302 to measure the magnetic fields generated by the magnetic coil 311. The H-field probe 302 may have different types. In one embodiment, the probe 302 is an H-field strength probe that can detect magnitude and frequency of the magnetic fields. In another embodiment, the probe 302 is an H-field phase probe that can detect phase information of the magnetic fields. The probe 302 may also differ in frequency ranges, H-field sensitivity levels, etc. Based on testing scenarios and requirements, a specific H-field probe can be selected. The H-field probe 302 is connected to the controller computer 305, which controls and moves the H-field probe 302 to different positions.

The magnetic coil 311 may be configured to couple with the feeding power supply 312. The feeding power supply 312 may be configured to supply power, e.g., an electrical current, to the magnetic coil 311. The amplifier 314 is configured to couple with the H-field probe 302 and the testing instrument 315, and amplify the testing data measured by the H-field probe 302. The cable 313 may be a 50 Ohm coaxial cable, and may be configured to connect the H-field probe 302, the amplifier 314 and the testing instrument 315.

The testing instrument 315 may be different depending on the testing requirements. In some embodiments, the testing instrument 315 may be a spectrum analyzer. It may be configured to receive the testing data from the amplifier 314, and perform a spectrum analysis on the testing data (the measured magnetic fields) to extract spectrum information of the measured magnetic fields. The testing instrument 315 may also be configured to connect with the controller computer 305 through the data cable 316. The data cable 316 can be a USB cable, a general purpose interface bus (GPIB) cable, or an Ethernet cable. The controller computer 305 may send controlling commands to the testing instrument 315, and the testing instrument 315 may deliver the analyzed testing data to the controller computer 305.

In some other embodiments, the system 300 may include a separate computer system, not mounted on the dock station 304, that is connected with the testing instrument 315, and is used to receive and analyze the testing data.

The above-discussed automated testing system 300 may also be used for different testing requirements and scenarios. In some embodiments, the system 300 may be configured to evaluate uniformity of the magnetic fields generated by the magnetic coil; in some embodiments, the system 300 may be used to identify a position of a main radiation source of a prototype PCB or a wireless charging related product; in some other embodiments, the system 300 may also be used to estimate strength and frequency of magnetic fields generated by a wireless charging related product (for example, a charging pad).

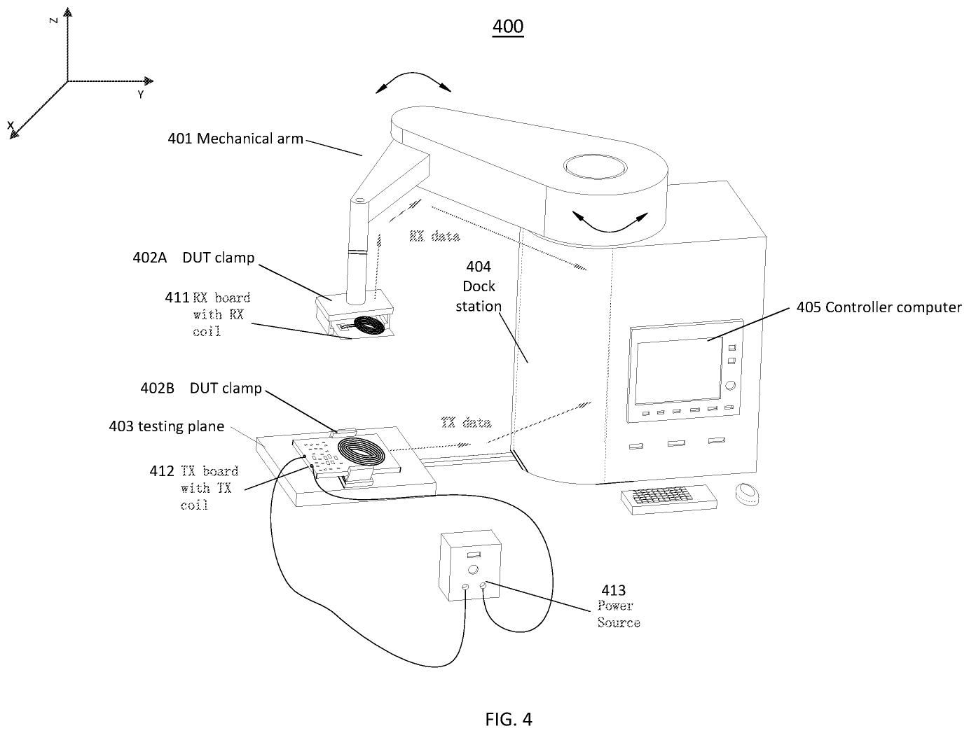

FIG. 4 shows an automated testing system 400 for measuring an efficiency and charging area of a wireless charging system, consistent with exemplary embodiments of the present disclosure. The system 400 may comprise a number of components, some of which may be optional. In some embodiments, the system 400 may include many more components than those shown in FIG. 4. However, it is not necessary that all of these components be shown in order to disclose an illustrative embodiment.

As shown in FIG. 4, the system 400 may include a mechanical arm 401, a DUT clamp 402A mounted on the mechanical arm 401, a testing plane 403, a DUT clamp 402B mounted on the testing plane 403, a dock station 404, a controller computer 405, as well as a RX board 411 with a RX coil, a TX board 412 with a TX coil, and a power source 413.

The DUT clamp 402A is a movable DUT clamp, mounted on the mechanical arm 401, and is configured to hold and move the RX board 411, or a wireless power receiver related product. The DUT clamp 402B is a stationary DUT clamp, placed on the testing plane 403, and is configured to hold the TX board 412, or a wireless charging pad.

The power source 413 is configured to supply power, e.g., an electrical current, to the TX board 412, which is configured to input the power to the TX coil. The TX coil may be magnetically coupled with the RX coil, and the RX coil is wireless charged by the TX coil. The power transferred during the wireless charging may be delivered to the RX board 411, which may be further output to a load.

The RX board 411 and TX board 412 may include a plurality of testing pins which can couple with the connectors, e.g., hook-up wires, on the DUT clamps 402A and 402B. The connectors allow the devices for testing to be electrically coupled and communicate with the controller computer or other testing instruments. Through the coupling between the testing pins and hook-up wires, an input voltage and current of the TX board 412, and an output voltage and current of the RX board 411 can be detected and transferred to the controller computer 405. Other parameters, such as a rectifier voltage on the RX board 411, can also be measured and transferred to the controller computer 405. The controller computer 405 may also determine a relative position between the TX and RX coils by moving the RX board 411 to any position within a defined range by the mechanical arm 401. Thus, the controller computer 405 is able to obtain parameters used for calculating a wireless charging efficiency at any relative position. The wireless charging efficiency at any relative position can be defined as:

$$η = \frac{{V}_{out} {I}_{out}}{{V}_{in} {I}_{in}}$$

Here, Vₒᵤₜ, Iₒᵤₜ, Vᵢₙ and Iᵢₙ stand for an output voltage, an output current of the RX coil and an input voltage, an input current of the TX coil respectively.

The above-discussed automated testing system 400 may also be used for different testing requirements and scenarios. In some embodiments, the system 400 may be configured to measure a charging efficiency at different distances and offsets between the TX and RX coils; in some embodiments, the system 400 may be used to characterize a charging area; in some other embodiments, the system 400 may also be used to monitor changes of parameters (e.g., rectifier voltage) during a wireless charging process.

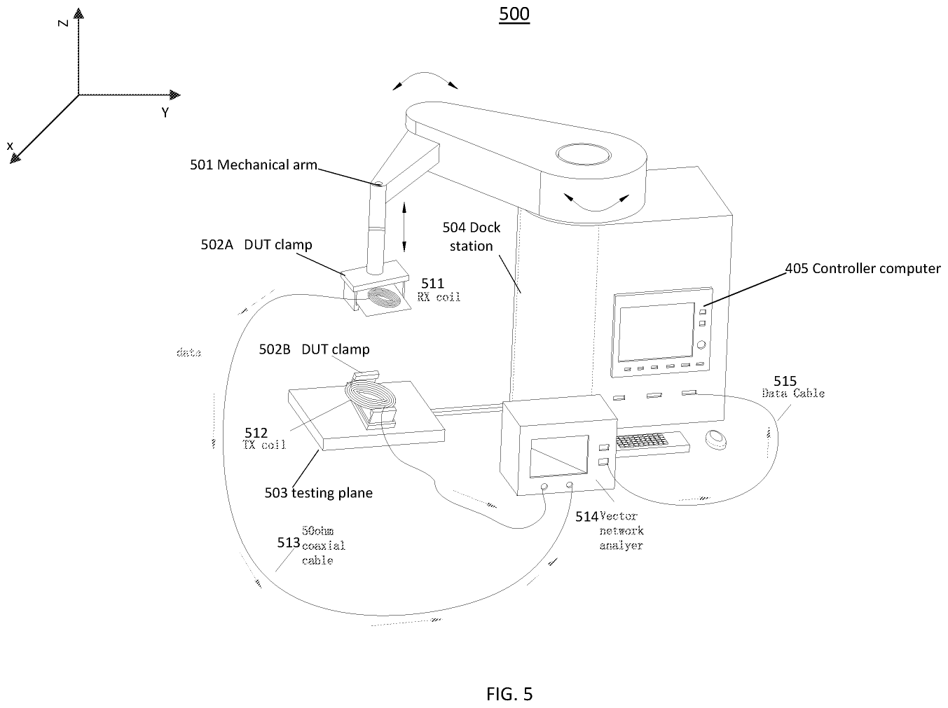

FIG. 5 shows an automated testing system 500 for measuring coupling coefficients, consistent with exemplary embodiments of the present disclosure. The system 500 may comprise a number of components, some of which may be optional. In some embodiments, the system 500 may include many more components than those shown in FIG. 5. However, it is not necessary that all of these components be shown in order to disclose an illustrative embodiment.

As shown in FIG. 5, the system 500 may include a mechanical arm 501, a DUT clamp 502A fixed on the mechanical arm 501, a testing plane 503, a DUT clamp 502B fixed on the testing plane 503, a dock station 504, a controller computer 505, as well as a RX coil 511, one or more TX coil 512, a cable 513, a testing instrument 514, and a data cable 515.

The DUT clamp 502A which is mounted on the mechanical arm 501, is a movable DUT clamp, and is configured to hold and move the RX coil 511. The DUT clamp 502B which is placed on the testing plane 503, is a stationary DUT clamp, and is configure to hold the TX coil 512. The TX coil 512 may include one or more TX coils that are placed at different positions. In some embodiments, additional magnetic materials, such as ferrite sheets can be attached to the TX and RX coils.

The cable 513 may be a 50 Ohm coaxial cable, and may be configured to connect the RX coil 511, the TX coil 512 and the testing instrument 514.

The testing instrument 514 may be different depending on the testing requirements. In some embodiments, the testing instrument 514 may be a vector network analyzer (VNA). The VNA 514 may include two ports: port 1 and port 2 which are connected with the TX and RX coils by the cable 513 respectively. The VNA 514 may also be configured to connect with the controller computer 505 through the data cable 515. The data cable 515 can be a USB cable, a general purpose interface bus (GPIB) cable, or an Ethernet cable. The controller computer 505 may send controlling commands to the VNA 514, and the VNA 514 may deliver testing results to the controller computer 505.

A VNA is a testing system that may be used to enable a radio frequency (RF) performance of RF and microwave devices to be characterized in terms of network scattering parameters (S-parameters). The S-parameters describe electrical behaviors of linear electrical networks when undergoing various steady state stimuli by electrical signals. Many electrical properties of networks of components (for example, inductors, capacitors, resistors) may be expressed using S-parameters. The S-parameters of the wireless charging system can be measured using the VNA 514 and sent to the controller computer 505. A coupling coefficient between the TX and RX coils then can be extracted from the S-parameters. Also, the measured S-parameters can help to build coil models for further simulation work.

The above-discussed automated testing system 500 may also be used for different testing requirements and scenarios. In some embodiments, the system 500 may be used to measure a coupling coefficient between the TX and RX coils at different distances and offsets; in some other embodiments, the system 500 may also be used to obtain parameters of a wireless charging system, such as self-inductance, mutual inductance, to establish simulation models.

Note that one or more of the functions described above can be performed by software or firmware stored in memory and executed by a processor, or stored in program storage and executed by a processor. The software or firmware can also be stored and/or transported within any non-transitory computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any medium that can contain or store the program for use by or in connection with the instruction execution system, apparatus, or device. The computer readable medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The invention described and claimed herein is not to be limited in scope by the specific preferred embodiments disclosed herein, as these embodiments are intended as illustrations of several aspects of the invention. Indeed, various modifications of the invention in addition to those shown and described herein will become apparent to those skilled in the art from the foregoing description. Such modifications are also intended to fall within the scope of the appended claims.

What is claimed is:

1. An automated testing system for testing a wireless charging system, comprising:
a mechanical arm configured to hold a first device-under-test (DUT) clamp;
a testing plane configured to hold a second DUT clamp;
a dock station connected to the mechanical arm; and
a controller computer configured to control the mechanical arm and receive testing data, wherein the second DUT clamp is configured to hold a device-under-test of the wireless charging system, and the first DUT clamp is configured to hold a testing device for testing the device-under-test and generating the testing data.

2. The system of claim 1, wherein the mechanical arm is configured to move the first DUT clamp in x, y and z directions, and rotate the first DUT clamp in a [−180, 180] degree range about a center axis of the first DUT clamp.

3. They system of claim 1, wherein the testing plane is a flat plane horizontally positioned with a surface of the plane parallel to an x-y plane.

4. The system of claim 1, wherein a testing device includes at least one of a magnetic coil, a printed circuit board (PCB), a magnetic probe, and a power receiver (RX) related electronic product.

5. The system of claim 1, wherein a device-under-test includes at least one of a magnetic coil, a PCB, and a power transmitter (TX) related electronic product.

6. The system of claim 1, wherein the controller computer further comprises a non-transitory computer-readable medium that stores program code to control testing processes, measure and analyze the testing data.

7. The system of claim 1, further comprising an internal data line in the mechanical arm, wherein the first DUT clamp is configured to communicate with the controller computer through the internal data line.

8. The system of claim 1, wherein the first DUT clamp includes a plurality of hook-up wires configured to be coupled to the testing device.

9. The system of claim 1, wherein the first DUT clamp includes a data connector for data exchanged between the testing device and the controller computer.

10. The system of claim 1, further comprising:
a feeding power supply configured to supply an electrical current to the device-under-test;
a probe held by the first DUT clamp;
a testing instrument configured to receive and analyze the testing data, and communicate with the controller computer through a data cable; and
an amplifier coupled with the probe and the testing instrument, and configured to amplify the testing data.

11. The system of claim 10, wherein the probe is an H-field strength probe configured to detect magnitude and frequency of magnetic fields generated by the device-under-test.

12. The system of claim 10, wherein the probe is an H-field phase probe configured to detect phase information of magnetic fields generated by the device-under-test.

13. The system of claim 10, wherein the testing instrument is a spectrum analyzer configured to perform a spectrum analysis on the testing data to extract spectrum information of magnetic fields generated by the device-under-test.

14. The system of claim 1, further comprising:
a RX board held by the first DUT clamp and coupled with a RX coil of the wireless charging system;
a TX board held by the second DUT clamp and couple with a TX coil of the wireless charging system; and
a power source configured to supply an electrical current to the TX board.

15. The system of claim 14, wherein the first DUT clamp is configured to measure an output voltage Vₒᵤₜ and an output current Iₒᵤₜ of the RX coil and transfer the measured signals to the controller computer.

16. The system of claim 15, wherein a charging efficiency of the wireless charging system at a relative position between the TX coil and the RX coil is calculated by
$$η = \frac{{V}_{out} {I}_{out}}{{V}_{in} {I}_{in}} ,$$
where Vᵢₙ is an input voltage and Iᵢₙ is an input current of the TX coil, and the relative position is controlled by the controller computer.

17. The system of claim 1, further comprising:
a RX coil of the wireless charging system held by and coupled with the first DUT clamp;
a TX coil of the wireless charging system held by and coupled with the second DUT clamp; and
a vector network analyzer configured to obtain S-parameters of the wireless charging system, wherein the vector network analyzer comprises two ports connected with the TX coil and the RX coil respectively, the vector network analyzer is configured to transfer the S-parameters to the controller computer, and the controller computer is configured to extract a coupling coefficient from the S-parameters.

18. The system of claim 17, further comprising ferrite sheets attached to the TX and RX coils.

19. An automated testing system for testing a wireless charging system, comprising:
a mechanical arm including a distal section configured to be releasably coupled to a plurality of types of devices selected from a clamp, a probe, and a testing device;
a testing plane configured to hold a device of the wireless charging system for testing;
a dock station connected to the mechanical arm; and
a controller computer configured to control the mechanical arm and receive testing data.

20. An automated testing system for testing a wireless charging system, comprising:
a mechanical arm configured to hold a first device-under-test (DUT) clamp;
a testing plane configured to hold a second DUT clamp;
a dock station connected to the mechanical arm; and
a controller computer configured to control the mechanical arm and receive testing data, wherein:
the first and second DUT clamps each include a connector configured to be electrically coupled with a device for testing; and
the mechanical arm comprises an internal data line configured to be coupled to a device coupled by the first DUT clamp to allow the device to communicate with the controller computer.
